(19) United States
(12) Patent Application Publication
(10) Pub. No.: US 2013/0258595 A1
(43) Pub. Date: Oct. 3, 2013

(54) Heat Transfer For Superconducting Integrated Circuits At Millikelvin Temperatures

(71) Applicant: David B. Tuckerman, Lafayette, CA (US)

(72) Inventor: David B. Tuckerman, Lafayette, CA (US)

(73) Assignee: MICROSOFT CORPORATION, Redmond, WA (US)

(21) Appl. No.: 13/431,482

(22) Filed: Mar. 27, 2012

(51) Int. Cl. H05K 7/20; F28D 15/00; F28F 7/00

(52) U.S. Cl. 361/701; 165/185; 165/104.11; 165/104.33

(57) ABSTRACT

Heat transfer is known to be a concern when scaling up a quantum computer. Some basic superconducting devices may dissipate some energy when switched and may interface in close proximity with the qubits. Highly conductive thermal vias may be used to transport hot electrons away from the qubits and into liquid ³He, which has relatively good bulk heat transport properties, such as relatively high thermal conductivity and heat capacity, at milliKelvin temperatures. Large Kapitza resistance between solids and liquid helium may present an issue getting the heat from the thermal vias to the liquid helium. However, Kapitza resistance may be minimized by using a porous open-cell metal ‘sponge’ having very high internal surface area per unit volume.

### TECHNICAL FIELD

Generally, this application relates to quantum computational systems. More specifically, the application relates to improving heat transfer for superconducting integrated circuits at milliKelvin temperatures.

### BACKGROUND

Heat transfer may be a concern when scaling up a quantum computer. For example, some basic superconducting devices may dissipate some energy when switched and may interface in close proximity with the qubits. For thin-film structures, the very poor electron-phonon coupling at ultralow (e.g., 10 mK) temperatures may be the biggest obstacle to heat transport within solids. This is because most heat is initially generated within electrically dissipative (resistive) elements in the form of energetic (‘hot’) electrons, but that thermal energy ultimately may be disposed to the environment through atomic or molecular motion.

The weak electron-phonon coupling creates a nonequlibrium situation where electron temperatures can be substantially higher than phonon temperatures. Thermal boundary resistance due to phonon reflections at solid-solid interfaces may be considered too, but due to the relatively high surface/volume ratio of thin film structures and the slightly weaker temperature dependence of the boundary conductance (e.g., T⁴ vs. T⁵), it turns out to be somewhat less of an obstacle than the electron-phonon coupling bottleneck.

### SUMMARY

Disclosed herein are methods, systems, and devices to improve heat transfer for superconducting integrated circuits at milliKelvin temperatures. Assuming that the electronic heat may be generated in, or may be efficiently coupled to normal (i.e., non-superconducting) high-purity metals such as copper, highly conductive thermal vias may be fabricated to facilitate the transport of hot electrons to the back of a substrate, which may be a more convenient location for heat removal. The hot electrons may then transfer their thermal energy into liquid ³He, which has relatively good bulk heat transport properties, such as relatively high thermal conductivity and heat capacity, at milliKelvin temperatures. However, large Kapitza resistance between solids and liquid helium may impede the flow of heat from the thermal vias to the liquid helium. This metal/³He Kapitza resistance Rₖ may restrict the total power dissipation on a qubit chip (QC). Kapitza resistance may be minimized by using a porous open-cell metal ‘sponge’ having very high internal surface area per unit volume.

The heat-dissipating sources of hot electronics, such as resistors for example, may need to be electrically isolated from each other for the circuitry on the QC to operate properly. In this situation, a QC may incorporate individual high-surface-area high-aspect-ratio porous metal heat exchange pin fins for each thermal via. In one possible embodiment where the heat exchange pin fins are immersed in a 10 mK ³He bath, the thermal resistance of such a design using traditional sintered silver having a surface area of ˜2 m²/gram is estimated to be 17 mK/pW for each thermal via (assuming they are spaced at least 10 μm apart). To limit the temperature rise to less than 5 mK above the bath temperature, power levels of no more than 0.3 pW per device (and less than 0.3 μW/cm² at the chip level) may be needed. In one example embodiment, nanomaterials, such as a nanomaterial that may include porous metal with surface areas of 20 m²/gram or more, may be used to improve the heat transfer by an order of magnitude or more beyond what may be achieved with traditional sintered silver materials.

The circuit architecture may permit one end of each resistor to be held at the same electrical potential, such as voltage, as the others. For example, one end of each resistor may be grounded. When one end of each resistor is grounded, the thermal vias may be tied together by a single large metal heat spreader, a portion of which may have a high internal (porous) surface area, for example a total area of ˜200 m², immersed in a ³He bath. Using known materials, the example embodiment may allow for thermal resistance of ˜100 K/W, implying that a maximum permissible total (i.e., all devices combined) heat load may be approximately 50 μW while still limiting the temperature rise to less than 5 mK. Operating at such high power levels may require careful attention to assure adequate mass flow within the ³He bath while simultaneously minimizing viscous heating. Direct immersion near the phase-change boundary within a dilution refrigerator's mixing chamber may be needed, for example, if more than 10 μW needs to be dissipated. Additionally, this embodiment may be applied to dissipative circuitry that may be coupled capacitively or magnetically to the qubits (i.e., no dc connection).

### BRIEF DESCRIPTION OF THE DRAWINGS

FIGS. 1A-C illustrates a cross section of an example embodiment of a structure that may improve heat transfer for superconducting integrated circuits at milliKelvin temperatures.

FIG. 2 illustrates a cross section of an example embodiment of another structure that may improve heat transfer for superconducting integrated circuits at milliKelvin temperatures.

FIG. 3 illustrates a top views example embodiments of structures that may improve heat transfer for superconducting integrated circuits at milliKelvin temperatures.

FIG. 4A-B illustrates a cross section of an example embodiment of thermal vias that may be used to improve heat transfer for superconducting integrated circuits at milliKelvin temperatures.

FIG. 5 illustrates a cross section an example embodiment wherein the front face of the qubit chip/wafer may be exposed to vacuum, and the rear face of the qubit chip/wafer may be in contact with liquid helium.

### DETAILED DESCRIPTION

Qubit unitary operations may be reversible and may be intrinsically non-dissipative. However, the processes of initialization (qubit state preparation) and readout generally may be dissipative. Some dissipative circuits may need to be in close proximity to the qubits.

A useful QC for factoring numbers with N>1000 bits may have, at the least, tens of thousands of qubits even for the most basic error correction that may be needed (one level of ‘magic state distillation’ multiplies the number of qubits 15-fold compared with an error-free system). There are tradeoffs between width and depth of the computation such that one may want a width of o(N²), in which case many millions of qubits may be used.

A limited amount of heat dissipation may be co-located on the same substrate as the qubits without major adverse effects. In another example, a larger amount of heat dissipation may be located on a separate substrate that may be in close physical proximity (e.g. face-to-face) to the qubit substrate. This may be used for both dc coupling and ac coupling.

Qubits may need to be maintained close to 10 mK, and may not be able to tolerate adjacent temperatures rising beyond 15 mK. Some qubits may be able to handle higher temperatures.

Phonon-electron interactions that facilitate equilibration of electron and phonon temperatures are known to be extremely weak at 10 mK. Thus, a non-equilibrium situation may be created where the phonons and the electrons may have radically different thermal energies. For example, phonons may be in local thermal equilibrium with themselves (exhibiting a Bose-Einstein distribution of energies), and the electrons may locally be in their own thermal equilibrium (but exhibiting a Fermi-Dirac distribution, and with a quite different temperature from the phonon temperature). Accordingly, it may be reasonably meaningful to simply speak of an ‘electron temperature’ Tₑ and a ‘phonon temperature’ Tₚ of a small volume element within a particular material.

Hot electrons (i.e., where Tₑ>>Tₚ) may present a concern as they may come from the environment. For example, hot electrons may be directly injected via external cabling, or may be excited by thermal radiation from nearby surfaces. Even if environmental influences may be completely eliminated, hot electrons may be generated by the dissipative elements in the qubit interface circuitry. In particular, thin-film resistors may develop relatively high electron temperatures at modest power levels. For example, a DC superconducting quantum interface device (SQUID) may contain a thin-film shunt resistor (necessary for its proper operation) which may dissipate only 1 pW of power, but may exhibit a 4-fold rise in electron temperature (Tₑ˜100 mK, vs. a substrate temperature of Tₚ=25 mK). This temperature rise may be primarily caused by the very weak coupling between electrons and phonons at ultralow temperatures. This coupling may have a very strong temperature dependence (T⁵); some non-negligible heating was discernible even at power levels 1000× lower, i.e., 1 fW. Although phonons may be within the thin-film resistor itself, its thickness of 90 nm may be less than the dominant phonon wavelength (˜2 μm) at the 25 mK temperature. Thus, a distinct phonon spectrum may not exist within the resistor, and coupling may occur directly to substrate phonon modes.

DC SQUIDS may be an interface circuit used for reading out qubits. When using a DC SQUID, hot electrons may contaminate the qubits that are being read. Even if the electrons may be kept fairly isolated, for example using Andreev reflection between the normal resistor and the superconducting electrodes or using magnetic coupling rather than direct coupling to qubits, the SQUIDS may generate noise in the measurement process. This may result in unacceptable error rates.

To improve sensitivity and minimize noise of a Superconducting Quantum Interference Device (“SQUID”), the size of the thin-film resistor may be increased. For example, the size of the thin-film resistor may be increased to have a 2,500× larger area and almost 10,000× larger volume than standard. This additional volume may be mostly inactive from an electrical circuit viewpoint, as it may not be in the current path. The enlarged resistor may act as a single cooling fin that may increase the volume available for electron-phonon coupling, which may allow the resistor to dissipate roughly 10,000× more power before its electronic self-heating begins to become noticeable (˜10 pW vs. 1 fW).

Although the single cooling fin may be useful for a single SQUID, this technique may not scale well to 50,000 or more SQUIDs on a single chip because each enlarged resistor may occupy an enormous area. For example, to maintain electron temperatures near 25 mK, a large resistor may be needed, having an area of 1.6 square millimeters; only 60 such resistors may fit on a 1 cm square die. To maintain electron temperatures near 10 mK, only one resistor may be used because of the T⁵ dependence of the electron-phonon coupling described above. This scaling problem may cast some doubt on the ability to use SQUIDs with interface circuitry that may be co-located on the same substrate. However, SQUIDS may be co-located on the same substrate by locating the qubits a safe distance away from the dissipative hot spots. For example, resistors might be allowed to locally get to electron temperatures as high as 1 K, yet if the qubit is located far enough away on the chip, everything may be perfectly fine. Another possibility may be to include the interface circuitry as part of a separate SQUID chip that faces the qubit chip/wafer with a sufficiently small gap that the qubits may be read out by magnetic coupling from the qubit chip/wafer to the SQUID chip. In either example, the hot electrons in the dissipative elements may not corrupt the qubits or the measurement process, by virtue of physical separation.

Andreev reflection notwithstanding, high-energy quasiparticles might make their way onto the superconducting wires and cause problems to qubits to which they are coupled. The flip-chip idea may be appealing, but there may be enhanced near-field radiative heat transfer; hot thermal electrons may couple to photons (i.e., they will radiate). The numbers might seem very small owing to the 4^{th} power dependence of the traditional Stefan-Boltzmann law blackbody radiation law, but it has already been observed by multiple experimenters that the 1 K thermal radiation from the walls of the “pot” in a dilution refrigerator may excite quasiparticles in superconductors that are in the general vicinity. The predominant photon wavelengths of a thermal radiator may be of the order λ_{T}=hc/kT , i.e., 2.3 mm for T=1 K. Radiative heat transfer between two surfaces may be enhanced by many orders of magnitude (>1000× enhancements above blackbody have been experimentally demonstrated) as the gap between the surfaces is reduced below λ_{T}; this phenomenon is sometimes called “photon tunneling”. Any qubit that may be electrically ‘close’ enough to be probed by a SQUID (through either direct coupling or magnetic coupling) may be closer than the thermal radiation wavelength, and therefore may be close enough to be corrupted by that thermal radiation.

The embodiments disclosed herein may alleviate the risks to the qubits from nearby dissipative elements, by providing improved heat transfer that minimizes the rise of electron temperatures in those dissipative elements.

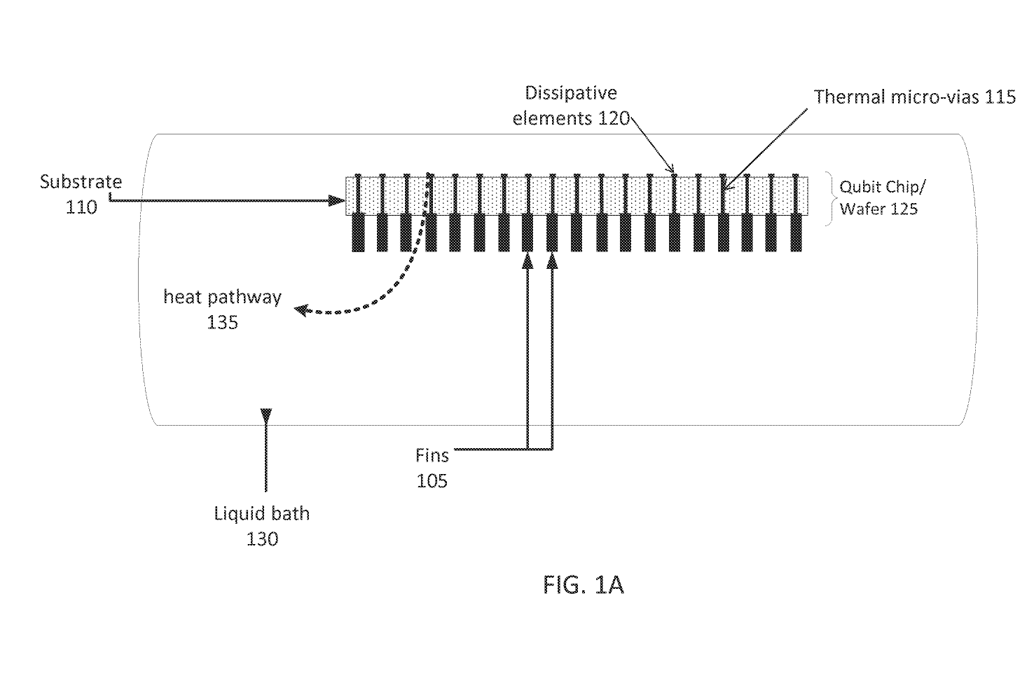

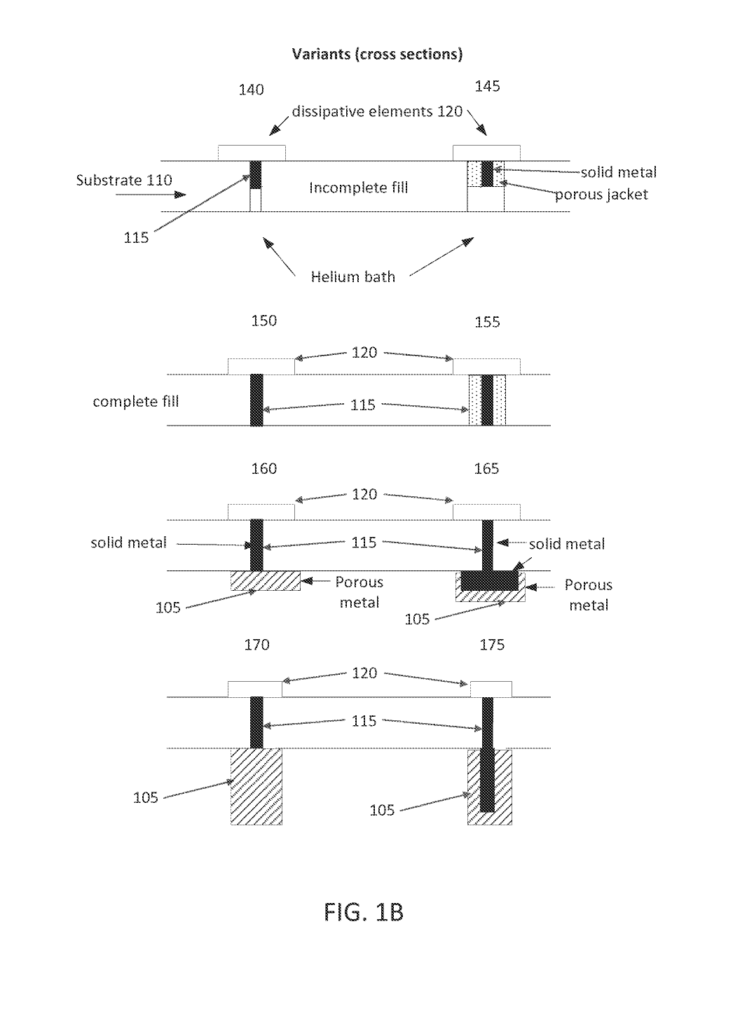

FIG. 1A illustrates an example embodiment of a structure to improve heat transfer for superconducting integrated circuits at milliKelvin temperatures. As shown in cross-sectional view in FIG. 1A, qubit chip/wafer 125 may comprise substrate 110, dissipative elements 120, thermal micro-vias 115, and optionally fins 105. Substrate 110 may be an electrical insulator such as sapphire, high-purity silicon, or the like. Dissipative elements 120 on the front face of substrate 110 may be resistors, Josephson devices, SQUIDS, or any electrical components that may act as a heat source. Qubit chip/wafer 125 may be a qubit chip/wafer containing various superconducting thin film elements. Thermal micro-vias 115 may be comprised of a thermally conductive non-superconducting metal, such as copper, silver, gold, platinum, or alloys of such metals. Thermal micro-vias 115 may be comprised of metal that may be solid, hollow, porous, or any combination thereof. As shown in cross section in FIG. 1A, the thermal micro-vias 115 may be an array of metal cylinders embedded within substrate 110. The top of each cylinder may be in direct electrical contact with the dissipative elements 120. The thermal micro-via 115 may fulfill the function of being a heat spreader. The thermal micro-via 115 may be of any dimension, for example a diameter of 3 microns and a length of 300 microns. At a temperature of 10 mK, this may imply a thermal resistance of Rₜₕ=L/kₜₕA=(300 μm)/[(2.56 W/m·K)π(1.5 μm²)]=0.017 mK/pW for each thermal via. This example may tolerate up to about 100 pW per thermal via without creating an excessive temperature rise, provided that sufficient heat transport exists at the other end of the thermal via. If no such heat transport is provided, then experimental data for electron-phonon coupling in an Au—Cu resistor may follow the relationship P˜(2.4·10⁹ W/K⁵m³)(Tₑ⁵−Tₚ⁵), which may imply for small ΔT that P/ΔT˜1.2·10¹⁰T⁴ W/m³K. If the same relationship holds for a copper thermal via, which has volume of π(1.5 μm)²·300 μm, an effective thermal resistance of 4000 mK/pW may be calculated.

If additional heat transfer is needed, fins 105 may be fabricated to extend outward from the rear face of substrate 110. Each fin in fins 105 may be in direct contact with a thermal micro via 115. Fins 105 may be comprised of a thermally conductive non-superconducting metal, such as copper, silver, gold, platinum, or alloys of such metals. Fins 105 may be comprised of metal that may be solid, hollow, porous, or any combination thereof. The fins may provide additional opportunity for electron-phonon coupling that may facilitate heat transfer to the substrate 110. For further improved heat transfer, fins 105 may be brought into direct contact with liquid helium, in which case fins 105 may have a porous structure with high internal surface area.

FIG. 1B illustrates cross sections of additional embodiments that may improve heat transfer for superconducting integrated circuits at milliKelvin temperatures.

As shown at 140 and 145, a qubit chip/wafer may comprise substrate 110, dissipative elements 120, and thermal micro-vias 115. Thermal micro-vias 115 may be comprised of a thermally conductive non-superconducting metal, such as copper, silver, gold, platinum, or alloys of such metals. Thermal micro-vias 115 may be comprised of metal that may be solid, hollow, porous, or any combination thereof. As shown in cross section at 140, the thermal micro-vias 115 may be embedded within substrate 110. The top of thermal micro-via 115 may be in direct electrical contact with a dissipative element 120. The thermal micro-via 115 may fulfill the function of being a heat spreader. Thermal micro-via 115 may incompletely fill a hole that has been bored in the substrate. For example, as shown at 140, thermal micro-via 115 may be half the thickness of substrate 110. Additionally, as shown at 145, thermal micro-via 115 may be solid metal and may be surrounded by a porous jacket.

Thermal micro-via 115 may also completely fill a hole that has been bored into the substrate. For example, at 150, thermal micro-via 115 may be of the same thickness as substrate 110. Thermal micro-via 115 may be solid metal and may be surrounded by a porous jacket as shown at 155.

Thermal micro-via 115 may be in direct contact with fins 105. Fins 105 may be comprised of a thermally conductive non-superconducting metal, such as copper, silver, gold, platinum, or alloys of such metals. Fins 105 may be comprised of metal that may be solid, hollow, porous, or any combination thereof. The fin may provide additional opportunity for electron-phonon coupling that may facilitate heat transfer to the substrate 110. As shown at 160, fins 105 may be made of porous material. As shown at 165, fins 105 may be made of solid metal that may optionally be covered by porous metal (as shown) and the metal portion of fins 105 may be in direct contact with thermal micro-via 115. As shown at 170 and 175, fins 105 may be of any length or width that may provide improved heat transfer. Fins 105 may also be brought into direct contact with liquid helium, in which case fins 105 may have a porous structure with high internal surface area.

FIG. 1C illustrates cross sections of additional embodiments that may improve heat transfer for superconducting integrated circuits at milliKelvin temperatures, where use of a liquid He bath may not be practical, and the substrate may be intended to be cooled through conduction to an external heat sink. For example, FIG. 1C may be used in embodiments where it may not be practical for a He bath to have direct contact with thermal micro-vias or fins.

As shown in FIG. 1C, thermal micro-via 115 may be a blind solid metal via that may be surrounded by substrate 110. Thermal micro-via 115 may also be a solid metal via that goes through substrate 110. Additionally, the thermal micro-via 115 may be a solid metal that goes through substrate 110 at one width and then increases in width after it passes through substrate 110.

Substrate 110 may be an electrical insulator such as sapphire, high-purity silicon, or the like. Dissipative elements 120 on the front face of substrate 110 may be resistors, Josephson devices, SQUIDS, or any electrical component that may act as a heat source. Qubit chip/wafer 125 may be a qubit chip or wafer containing various superconducting thin film elements. Thermal micro-vias 115 may be comprised of a thermally conductive non-superconducting metal, such as copper, silver, gold, platinum, or alloys of such metals. Thermal micro-vias 115 may be comprised of metal that may be solid, hollow, porous, or any combination thereof. As shown in cross section in FIG. 1A, the thermal micro-vias 115 may be an array of metal cylinders embedded within substrate 110. The top of each cylinder may be in direct electrical contact with a dissipative element from the dissipative elements 120. The thermal micro-via 115 may fulfill the function of being a heat spreader.

In another example embodiment, thermal performance may be improved by designing the circuit architecture such that one terminal of every dissipative element, which may be resistors, may be held at ground potential or some other fixed voltage. This type of architecture may be possible in circuit families and sensing methods that may rely primarily on magnetic or capacitive coupling rather than direct coupling.

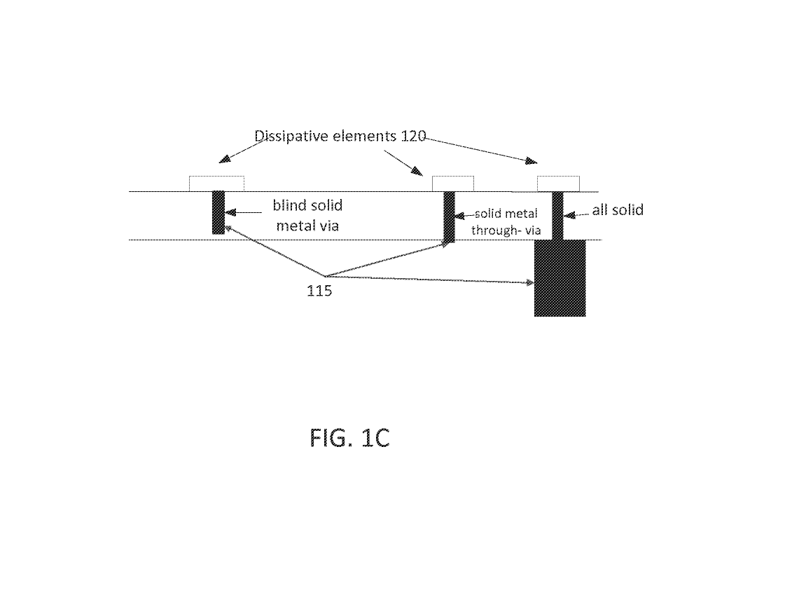

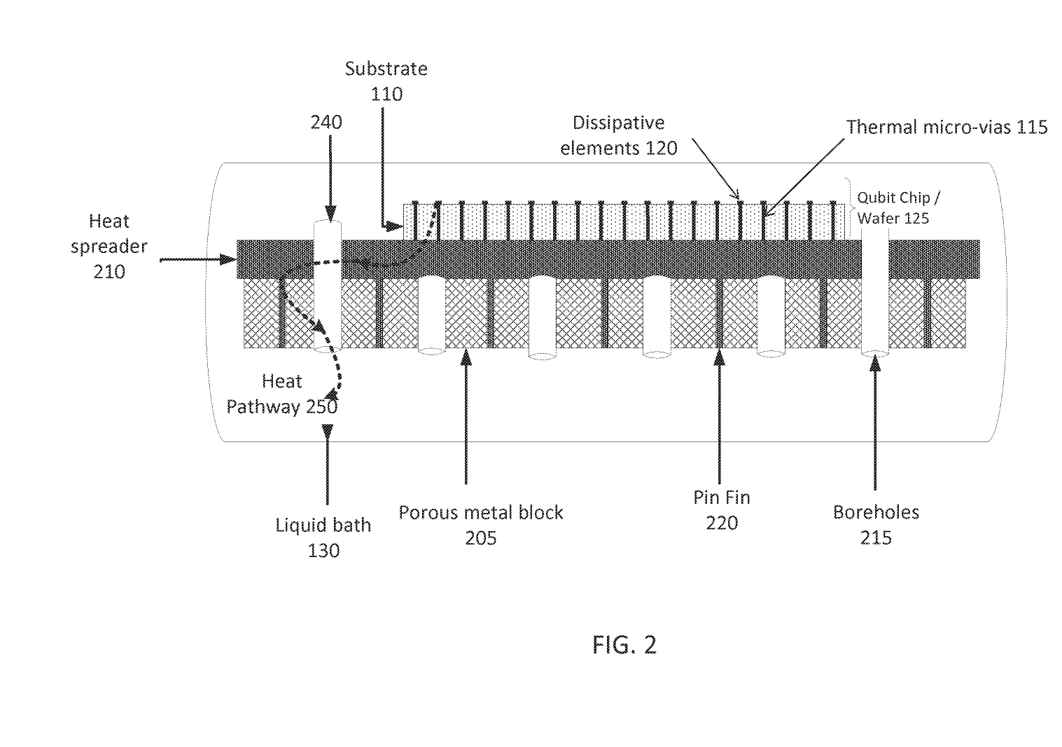

In that situation, FIG. 2 illustrates how the rear face of substrate 110 may be in contact with a thermally conductive metal heat spreader 210, such as a copper backing Thermal micro-vias 115 may terminate at the heat spreader 210, and may therefore be electrically and thermally short-circuited together in this configuration. As illustrated in FIG. 2, heat spreader 210 may be bonded to a porous (for example, sintered) copper or silver block at 205 that it is contact with ³He. If it is not feasible to bring liquid helium in contact with the rear of the qubit chip/wafer, then the porous block at 205 may not be needed, and heat may instead be transferred by conduction to the refrigeration system, for example using copper or silver metal conductors.

In one example embodiment, coupling directly from the copper to liquid helium (which is where the heat ultimately may go) may occur instead of going indirectly through the substrate phonons. The Kapitza resistance may be high at low temperatures, owing to the very large mismatch in acoustic impedances (which are the product of density and sound velocity) between solids and liquid He. According to the classical ‘acoustic mismatch model’, the vastly differing speed of sounds may cause most phonons to be reflected back when they encounter the solid/He interface. This phenomenon may be analogous to the familiar optical ‘total internal reflection’ that is used to confine light in optical fibers. Only a few phonons that are at near-normal incidence are candidates to transmit energy. Due to the very large mismatch in acoustic impedance, the transmission coefficient for even this subset of phonons may be quite small; most of them still get internally reflected (a phenomenon quite familiar from electrical transmission line theory). While this may be a classical model, and quantum mechanical corrections may be needed when working with a quantum liquid such as helium that tend to improve the coupling by roughly an order of magnitude, both models may predict a thermal resistance having a T⁻³ dependence. In the 10-100 mK region, measurements for flat surfaces of copper in liquid helium may show R_{K}˜C/AT³ where C may be in the range of 0.005 to 0.05 m²K⁴/W depending on the type of copper and the isotope of helium (⁴He, ³He, or a mixture). This coefficient may be an order of magnitude lower (i.e., C˜0.01 m²K⁴/W) for alloys of copper such as Cu—Ni, Cu—Cr, or Cu—Zn (aka brass). This may be due to surface roughness and/or magnetism. Using these lower figures, it may imply a surface area of A=2500 square microns simply to match the 4000 mK/pW thermal resistance calculated for the substrate coupling. This may imply extending the thermal via by about an additional 250 μm into the liquid helium, much like a pin fin heat sink. Accordingly, the embodiments disclosed herein may utilize nanoporous materials to achieve improved heat transfer.

As shown in FIG. 1A, the back of qubit chip/wafer 125 may be immersed in liquid bath 130. The front of qubit chip/wafer 125 may also be immersed in the bath, or it may be sealed in vacuum. The liquid bath 130 may be ³He, ⁴He, or a combination of ³He and ⁴He, a superfluid, or some other heat transfer fluid that is liquid at the desired operating temperature. For example, liquid bath 130 may be comprised of pure ³He.

Superfluids, such as superfluid ⁴He (aka “helium II”) may have superb heat-transfer characteristics in the 1-2 K temperature range. ⁴He may act as if it may have nearly infinite thermal conductivity. However, in the milliKelvin regime, the heat capacity and the thermal conductivity of ⁴He may fall off rapidly with temperature, both as T³; in addition, the thermal conductivity may have a linear dependence on the diameter of the channel through which it flows (essentially the channel dimension acts as the mean-free path). In contrast, the heat capacity of ³He may fall off only linearly (Fermi liquid statistics) and the thermal conductivity may fall off only as T″² down to about 100 mK, below which it may start to increase as 1/T owing to the increase in mean free path. However, the viscosity of ³He may also increase rapidly as 1/T²; care must be taken not to create high-shear flow situations that could induce viscous heating. As a result, the microchannel convection cooling techniques that work at room temperature may be counterproductive at 10 mK. Thus, when operating at 10 mK, the heat capacity discrepancy may be large, more than 6 orders of magnitude larger for ³He than for ⁴He. ³He may also have a far higher heat capacity than copper by about 4 orders of magnitude in the sub-kelvin regime. Its Fermi energy may be the order of a few K, vs. 10000 K for copper. Thus, a far greater volume fraction of its Fermi sphere may be excited at low temperatures. As a result, ³He may create an excellent constant-temperature bath to be used for liquid bath 130. While ³He may be rare and expensive, it may be present in dilution refrigerators. In one example embodiment, access to pure liquid ³He may be accomplished by placing qubit chip/wafer 125 inside the upper portion of a mixing chamber of the dilution refrigerator. It may also possible to create a separate cell to hold ³He, which may then be thermally strapped using, for example, high-purity copper to the mixing chamber. This may prevent disturbing the integrity of the mixing chamber. However, this may also require an additional sintered heat exchanger to be immersed in that separate cell.

FIG. 2 illustrates another example embodiment of a structure to improve heat transfer for superconducting integrated circuits at milliKelvin temperatures. As shown in FIG. 2, qubit chip/wafer 125 may comprise substrate 110, and/or thermal micro-vias 115. Qubit chip/wafer 125 may be a qubit chip or wafer that dissipates less than 50 μW/cm². At 115, thermal micro-vias may be placed vertically within substrate 110. For example, the fins may be vertical columns within substrate 110. Substrate 110 may be an electrical insulator such as sapphire, silicon, or the like. Thermal micro-vias 115 may be comprised of a thermally conductive metal, such as nanoporous copper (Cu), solid Cu, silver, gold, platinum, or other non-superconductive metals. The thermal micro-vias 115 may be an array of metal cylinders embedded within substrate 110. The top of each cylinder may be in contact with a dissipative element from the dissipative elements 120. Dissipative elements 120 may be resistors, a Josephson devices, SQUIDS, or any electrical components that may act as a heat source. The thermal micro-via 115 may assist to spread heat. The thermal micro-via 115 may be of any dimension or shape.

As shown in FIG. 2, qubit chip/wafer 125 may be coupled to heat spreader 210. This may be done, for example, to spread heat away from the qubit, such as illustrated by heat pathway 250. Heat spreader 210 may be comprised of a thermally conductive non-superconductive metal, such as nanoporous copper (Cu), solid Cu, silver, gold, platinum, or the like.

At 205, nanoporous material, or sintered material may be used to increase surface area, reduce Kapitza resistance, and/or distribute heat away from qubit chip/wafer 125.

Sintered metal, such as copper, silver, platinum, or the like may be created by hot-pressing metal nanoparticles in a mold. A reducing atmosphere (H₂) may be used to avoid oxidation and encourage fusing of the particles into a sponge-like structure. Sintered metal may have roughly 50% of bulk density. Generally, the surface area for a given volume of material varies as the reciprocal of the particle size used, so smaller particles may produce much higher surface areas. The sinters that may be used in milliKelvin heat exchangers may be made from submicron particles; 80 nm particles, for example, may be a good selection for a high-performance heat exchanger having an internal surface area of ˜2 m²/gram (this area is customarily measured using the Brunauer-Emmett-Teller, or “BET” method).

Besides providing an enhanced surface area, the sinters may also improve the efficiency of phonon transfer by creating an improved acoustic impedance match at 205 to a liquid helium bath. This may be because the sintered material has a much lower effective elastic modulus (by 1 to 2 orders of magnitude), so it may be acoustically softer and a closer impedance match to the liquid helium. Additionally, it may also create a much higher available phonon density of states at low energies than exists in bulk metal. Those effects may help the heat transfer. On the other hand, the nanoscale features of the sinter may create scattering of electrons and phonons than may occur when using bulk metal. The nanoscale features of sinter may also reduce the effective thermal conductivity of the liquid helium in the pores owing to the reduction in mean free path. These effects may reduce the effectiveness of the heat exchange. Because of these complex effects, one may not be able to rely on the published Kapitza resistance data for a unit area of flat surface and extrapolate it to sinters simply by multiplying the figure by this very large surface area.

As an example, at 10 mK, typical measured Kapitza resistances for silver sinters of ˜50 nm particles are of the order R_{K}˜(2·10⁴ m² K/W)/A where A is the internal surface area of the sinter. It may be likely that copper sinters will exhibit similar performance as silver and have similar electrical and acoustic properties. Thermal vias may be expected to have a thermal resistance of 0.017 mK/pW, and so a sintered area of ˜10⁻³ m² may be needed to obtain a Kapitza resistance equal to that. This may require 0.5 mg of metal (assuming an internal area of 2 m²/g). Assuming a density that may be 50% of bulk, a volume of 0.1 mm³ of sintered material may be needed. This may be a larger volume than may be attached to each thermal via. Even if the sintered cross section of the micro-via was expanded from a 3 μm circle to a 10 μm square, that may still require a length of ˜1000 mm, which may be impractical. With a 10×10×1000 micron sintered ‘tail’, Kapitza resistance may therefore be 1,000 times larger than thermal via resistance, i.e., ˜17 mK/pW, which may mean that each via may need to be limited to ˜0.3 pW. This may be low power for any type of traditional Josephson circuit. For example, the dynamic energy from switching of a low-power ‘ERSFQ’ type gate with current I_{c}=50 μA may be on the order of 10⁻¹⁹ J, which may limit clock frequency to only ˜3 MHz. However, since the circuit may operate at 10 mK rather than 4.2 K, a lower current may be used for the RSFQ gate, which may reduce the power consumption in proportion to the current.

It may be possible that I_{c} will scale directly with temperature. In this scenario, 1 μA currents may be used, in which case the dynamic switching current is of order Φo·Ic=(2·10⁻¹⁵ V·s)(1·10⁻⁶ A)=2·10⁻²¹ J. The clock frequency may then be as high as a 150 MHz.

The Kapitza resistance between metal and ³He may be a bottleneck in cooling hot electrons generated by dissipative circuits in a 10 mK environment, even with the use of sintered metals to increase surface area. This may present an issue for building a scaled-up quantum computer. For example, in the Josephson qubit field, a typical clock frequency may be 10 MHz for a cycle of initialization, qubit operations, and readout. Scale the qubit count by 4 or 5 orders of magnitude, and increase the pace of qubit manipulation by 2 or 3 orders of magnitude, and this may increase the heating by 6 to 8 orders of magnitude.

In one example embodiment, nano materials may be used at 205 to achieve improvements in heat transfer in superfluids. The nanoporous metals may be synthesized to increase the surface/volume ratio by another order of magnitude. For example, metal alloy may be processed with an electrochemical ‘dealloying’ process that may remove its less noble component(s) and thereby produce sponge metal catalysts, in analogy to Raney Nickel, which may be formed by dealloying Al from Al:Ni. Such sponge metal catalysis may have improved surface area. For example, Raney nickel typically has a surface area of 100 m²/g, which may be 50× more than the typical sintered metal heat exchangers. As another example, nanoporous metals may be synthesized using dezincification, such as when porous copper is naturally created from dezincification corrosion of brass.

In one example embodiment, pin fin 220 may be attached and thermally coupled to heat spreader 210 and to nanoporous material 205. This may be done, for example to create a hierarchical microstructure, where there may be some wide metallic heat conduction paths within the metal in parallel with the nanoporous material 205. Pin fin 220 may be comprised of a thermally conductive material, such as nanoporous copper (Cu), solid Cu, silver, gold, platinum, or the like. In one example embodiment, pin fin 220 may be comprised of non-superconductive material. Additionally, boreholes 215 may be created within nanoporous material 205 and may go through nanoporous material 205, substrate 110 (shown at 240), and/or qubit chip/wafer 125. This may be done, for example, to provide intermingling channels for cooling liquid from liquid bath 130 that may improve heat transfer within nanoporous material 205.

As discussed above, heat conduction in sintered metals may be compromised by the degradation in thermal conductivity of the metal and of the ³He permeating the sinter, due to the nanoporous structure that may create very short mean free paths compared with bulk metal. For example at a temperature of 4 K, the silver sinters typically have resistance values of around 10 μΩ-cm. Assuming this value remains the same at further reduced temperatures (as may usually the case for metals where impurity/defect scattering is dominant), and applying the Wiedemann-Franz law, this may impute a thermal conductivity of 2.45·10⁻³ W/m·K at T=10 mK. Recalling that one embodiment estimated 3 μm Cu thermal vias to have a thermal conductivity of 2.56 W/m·K; this may mean that the sintered silver is 1000× less conductive than a solid silver via. Thus a hierarchical microstructure, where pin fin 220 may provide metallic heat conduction paths within the heater spreader 210, as well as wide boreholes 215 for ³He conduction, may improve heat transfer within the sponge and allow larger sponges to be used. An analogy to this embodiment may be the human circulatory and respiratory systems, each of which may include a hierarchical tree or fractal-like structure of decreasing channel sizes and membrane thicknesses, with corresponding increases in surface areas, until the actual oxygen and CO₂ transfer occurs at a very small scale by diffusion across nanoscale cell interfaces having a very large total surface area (hundreds of square meters).

An intermediate coating or a graded structure may be used at the surfaces of pin fin 220, nanoporous material 205, and/or boreholes 215 to provide a less abrupt transition between metal and liquid helium and hence improved thermal boundary resistance.

Nanoporous material 205, heater spreader 210, and/or pin fin 220 may be coated with one or more monolayers of magnetic material. The presence of magnetic impurities such as Fe or Gd in metals may improve the thermal contact below 20 mK, such that R_{K} varies only as T⁻¹ rather than the much stronger T⁻³ dependence exhibited at higher temperatures. To take advantage of this magnetic channel, it may be necessary to ensure that there are no adsorbed ⁴He atoms inside the nanoporous material. Accordingly, the sample may not be placed inside a mixing chamber of a dilution refrigerator, as it will be contaminated with ⁴He. Thus, a separate cell containing pure ³He may need to be used.

As described herein, nanoporous heat exchangers may be attached to each thermal via and may be 10× more effective than the published data for large sintered blocks. This may imply that thermal resistances may be in the range of 1.7 mK/pW for each discrete heat exchange fin instead of 17 mK/pW. Thus, it may permit circuits to operate at levels of a several pW, rather than a small fraction of a pW. ERSFQ/eSFQ type logic, having no static power dissipation, may be usable in either of these cases, provided the clock frequency may be slowed sufficiently. The use of Josephson junctions with ultralow currents I_{c} may help further reduce power dissipation, although doing so may require the use of proportionally higher value inductors (since generally the product L·I_{c} needs to have a value which has the same order of magnitude as a flux quantum) which may make the devices large.

The embodiments described herein may provide an architecture whereby all of the dissipative elements may have one end tied to a common ground. In this case, discrete high aspect ratio heat exchanger fins, such as shown in FIG. 1A, may not be needed. Rather, a monolithic heat exchanger, such as shown in FIG. 2, may be employed. For example, the heat exchanger may be 10 mm thick and 50 mm in diameter (i.e., acting as a heat spreader). Owing to the ˜1000-fold increase in heat exchanger volume, higher heat loads may be cooled. For example, with an internal surface area of ˜200 m², the overall thermal resistance may be ˜100 K/W for the QC chip. This may indicate that the circuit may tolerate a total heat dissipation of 10 (and perhaps even 50) μW for the entire computer, which for 1 million dissipative elements may imply 10 or 50 pW/element.

To maintain a temperature rise of only 1 mK in an isolated ³He bath at 50 μW, a recirculation may need to occur at a rate of 8 cc/second. This may be challenging when considering viscous heating effects. However, this may be addressed by co-locating the mixing chamber with the phase boundary, so that the heated helium may transfer across the phase boundary. This may allow one to take the advantage of the quite high latent heat associated with the phase change (‘evaporation’ of ³He into a dilute ³He/⁴He), rather than trying to create a traditional convective flow that relies on the heat capacity of fluid.

Thermal vias may be centered directly underneath the dissipative elements, such as resistive element. This may be done, for example, to prevent electrons from having to conduct through a thin film, which may create a troublesome thermal transient. Heat from the dissipative elements may be generated in short pulses, but may be dissipated over long periods. This means there may be a possibility of creating thermal transients where the peak temperature may be significantly larger than the average temperature, which may radiate a burst of energy (phononic and possibly electromagnetic) that may be troublesome to nearby sensitive qubits. A clocked system may, at startup, exhibit a sawtooth-like temperature profile at each dissipative element, where each individual sawtooth may have a characteristic decay time that may be determined by local thermal time constants. Each successive sawtooth may be slightly warmer than the previous one, until a stable sawtooth profile may be reached. The time for this stabilization to occur may be determined by the system's global thermal time constant.

The temperature rise of an individual sawtooth may be compared with the steady-state temperature. For example, in an RSFQ device, the energy associated with a flux quantum transition may be of the order Φₒ·I_{c}. A current of 10 μA may imply an energy of 2.10⁻²⁰ J. Dividing by the heat capacity of copper at 10 mK, which may be 1.6 J/m³K, may predict a transient temperature rise of 12.5 mK·(μm)³. This may mean that, for an example embodiment with a 3 μm diameter cylindrical thermal via, a ˜1 mK temperature rise may be experienced if the heat is distributed uniformly over 1.7 μm of cylinder length. Considering that the thermal diffusivity of copper at 10 mK with a 3 μm mean free path may be 1.6 m²/s=1.6 μm²/ps, a transient heat burst may not be a problem as long as the burst of heat occurs over a time scale significantly longer than 1 ps.

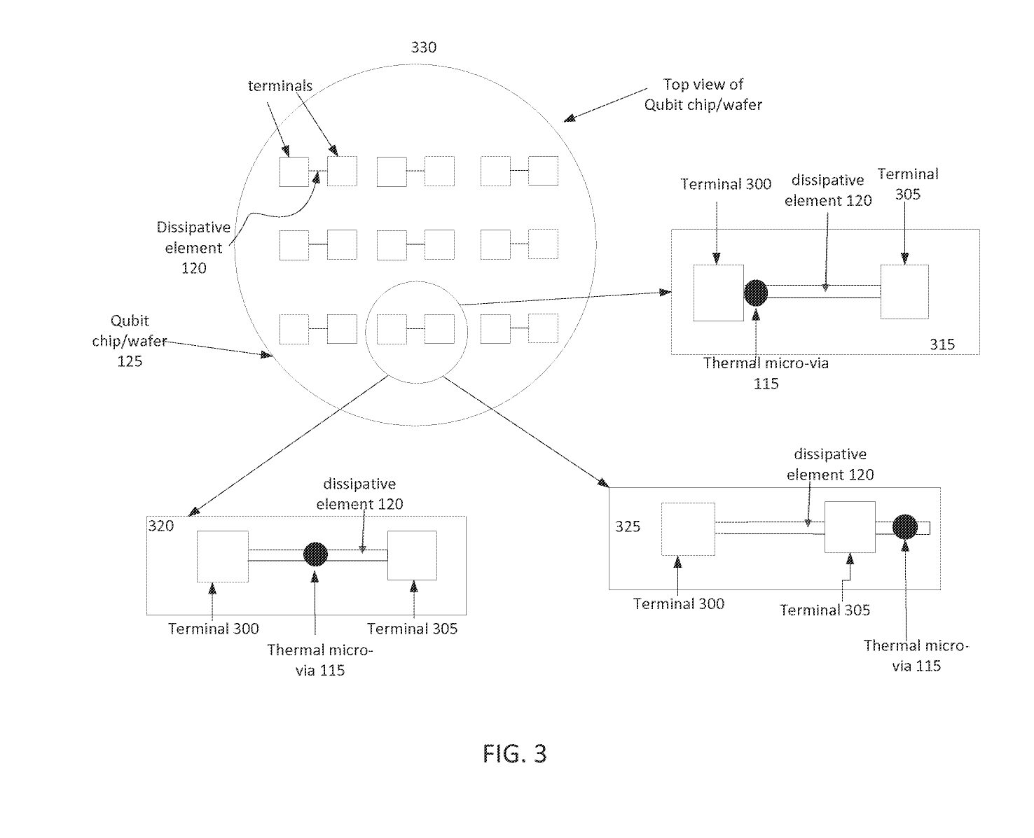

FIG. 3 illustrates top views of example embodiments of structures that may improve heat transfer for superconducting integrated circuits at milliKelvin temperatures. A top view of a qubit chip/wafer may be seen at 330. As shown at 330, the top of a qubit chip/wafer may have terminals that connect to a dissipative element, such as dissipative elements 120.

At 320, a close up of an embodiment may be seen where thermal micro-via 115 may be in contact with the center of dissipative element 120. Dissipative element 120 may be in contact with terminal 300 and terminal 305. Terminal 300 and terminal 305 may be connected to the substrate of the qubit chip or wafer.

At 325, a close up of an embodiment may be seen where thermal micro-via 115 may be in contact with an end of dissipative element 120 that extends beyond a terminal, such as terminal 305. Such a configuration may be desirable in architectures where terminals of the micro-vias may be connected to the same voltage potential. Dissipative element 120 may be in contact with terminal 300 and terminal 305. Terminal 300 and terminal 305 may be connected to the substrate of the qubit chip or wafer.

At 315, a close up of an embodiment may be seen where thermal micro-via 115 may be in contact with dissipative element 120. Thermal micro-via 115 may contact any location along dissipative element 120. For example, thermal micro-via 115 may be located at the far right or left of dissipative element 120, which may be at or near a terminal of dissipative element 120. Dissipative element 120 may be in contact with terminal 300 and terminal 305. Terminal 300 and terminal 305 may be connected to the substrate of the qubit chip/wafer.

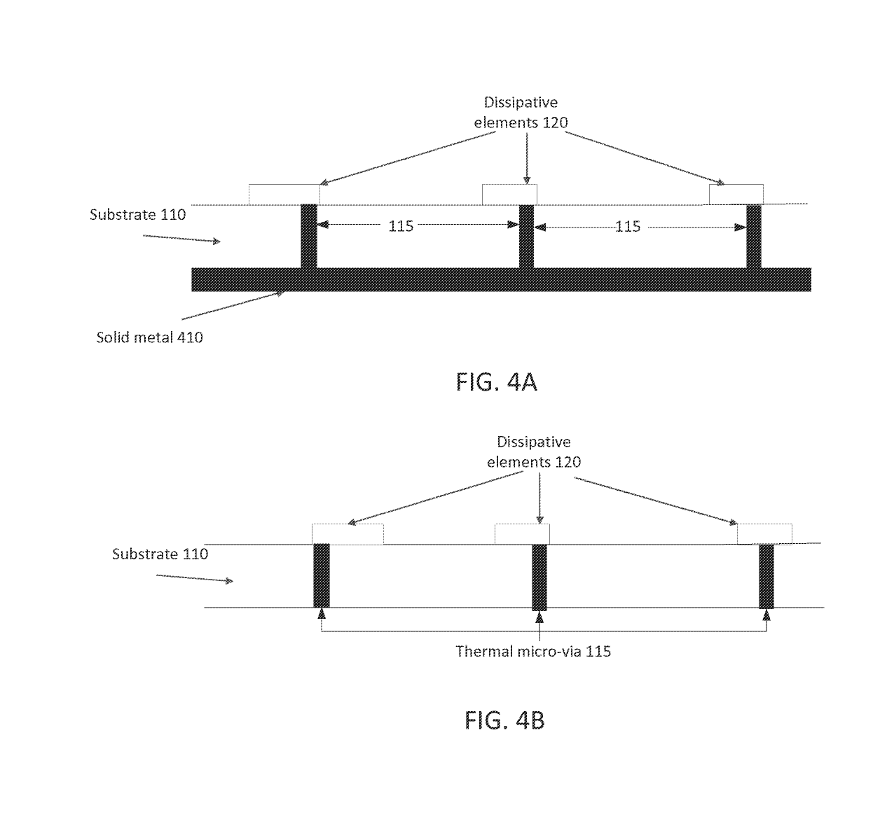

FIGS. 4A-B illustrate cross sections of example embodiments of thermal vias that may be used to improve heat transfer for superconducting integrated circuits at milliKelvin temperatures. As shown in FIG. 4A, thermal performance may be improved by designing the circuit architecture such that one terminal of every dissipative element in dissipative elements 120, which may be resistors, may be held at ground potential or some other fixed voltage. This type of architecture may be possible in circuit families and sensing methods that may rely primarily on magnetic or capacitive coupling rather than direct coupling. The rear face of substrate 110 may be in contact with a thermally conductive solid metal 410 that may act as a heat spreader. The solid metal may be a copper backing Thermal micro-vias 115 may terminate at solid metal 410, and may therefore be electrically and thermally short-circuited together in this configuration. Because it may not be feasible to bring liquid helium in contact with the rear of the qubit chip/wafer, heat may instead be transferred by conduction to the refrigeration system, for example using copper or silver metal conductors.

As shown in FIG. 4B, thermal micro-vias 115 may comprises solid metal that may be surrounded by substrate 110 or may comprise a solid metal via that extends beyond substrate 110. Thermal micro-via 115 may be in direct contact with a portion of dissipative elements 120. For example, thermal micro-via 115 may contact any location along dissipative elements 120, such as the center of dissipative elements 120.

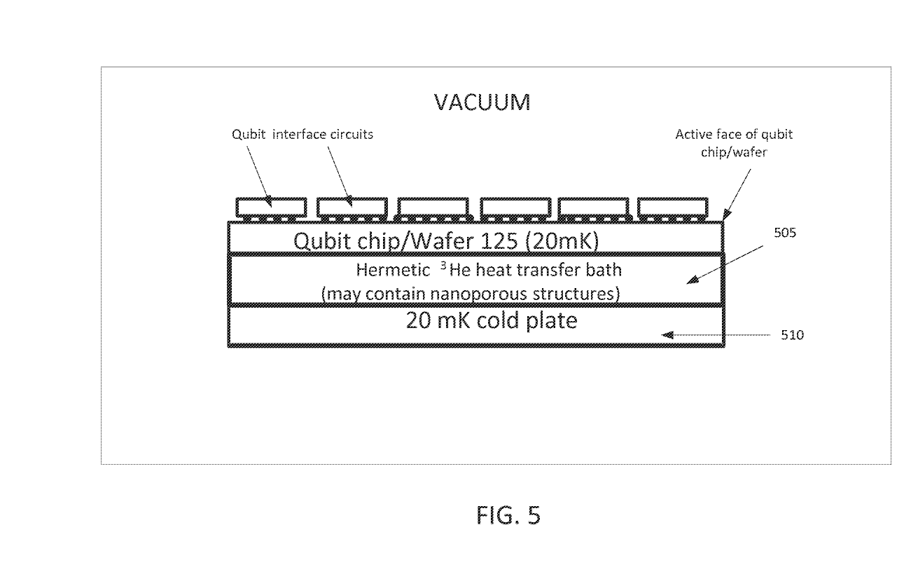

FIG. 5 illustrates a cross section of an example embodiment wherein the active face of the qubit chip/wafer may be exposed to a vacuum, and the rear face of the qubit chip may be in contact with a sealed bath of liquid helium. The face of the qubit chip/wafer that is in contact with the active qubits may be referred to as the active face of the qubit chip/wafer.

It is not necessary that the entire assembly of qubit chip/wafer and heat exchangers be immersed in a liquid ³He bath. For example, as illustrated in FIG. 5, the active face of the qubit chip/wafer may be exposed to a vacuum, rather than being immersed in liquid ³He. In such instance, the backside of the qubit chip/wafer may still be exposed to a liquid ³He bath by constructing a hermetically sealed enclosure to confine the liquid ³He. For example, as shown in FIG. 5 at 505, qubit chip/wafer 125 may be in contact with a hermetically sealed enclosure that confines liquid ³He such that the back of qubit chip/wafer 125 may be in direct contact with the liquid ³He. For example, thermal micro-vias and/or fins may be in direct contact with the liquid ³He.

As shown at 510, a separate cold plate may be in contact with the hermetically sealed liquid ³He. The cold plate may be used to maintain the liquid ³He at a desired temperature, for example 20 mK. The cold plate may be in contact with a refrigerator or other heat-sinking device.

What is claimed:

1. A heat exchanging apparatus for superconducting integrated circuits operating at milliKelvin temperatures, the apparatus comprising:
a substrate having a first surface and a second surface opposite from each other, the first surface being coupled to a dissipative element having at least two electrical terminals; and
a thermal micro-via positioned in physical contact with a portion of the dissipative element and extending towards the second surface in a perpendicular direction;
wherein at least a portion of the substrate is maintained at a temperature of less than 100 milliKelvin.

2. The apparatus of claim 1, wherein the first surface is coupled to a dissipative element such that a terminal of the dissipative element is at the same electrical potential as a terminal of a second dissipative element.

3. The apparatus of claim 2, wherein the second surface has a metal backing in contact with the thermal micro-via.

4. The apparatus of claim 2, wherein the dissipative element is in electrical contact with a superconductor.

5. The apparatus of claim 1, wherein the thermal micro-via comprises a non-superconductive material.

6. The apparatus of claim 5, wherein the thermal micro-via comprises copper, silver, gold, platinum, or alloys thereof

7. The apparatus of claim 1, further comprising a metal fin coupled to the thermal micro-via and extending from the substrate.

8. The apparatus of claim 7, further comprising a helium bath in contact with the metal fin.

9. The apparatus of claim 8, wherein the metal fin comprises a porous material.

10. A heat exchanging apparatus for superconducting integrated circuits operating at milliKelvin temperatures, the apparatus comprising:
one or more dissipative elements;
a substrate for providing electrical insulation for the one or more dissipative elements;
one or more thermal micro-vias for transporting heat through the substrate and away from the one or more dissipative elements; and
a liquid helium bath for transporting heat from the one or more thermal micro-vias.

11. The apparatus of claim 10, wherein the one or more dissipative elements have respective terminals at the same electrical potential.

12. The apparatus of claim 10, wherein the one or more thermal micro-vias transport heat through the substrate and away from the one or more dissipative elements by providing a thermal resistance that is lower than that of the substrate.

13. The apparatus of claim 10, wherein the one or more thermal micro-vias provide a scattering center for reducing electron temperatures in the one or more dissipative elements.

14. The apparatus of claim 10, further comprising a heat spreader for transporting heat from the one or more thermal micro-vias.

15. The apparatus of claim 14, further comprising porous material to transport heat away from the thermal micro-vias and into the liquid helium bath.

16. The apparatus of claim 15, further comprising at least a borehole, the borehole penetrating through the porous material to provide intermingling channels for the liquid helium bath.

17. The apparatus of claim 10, wherein the liquid He bath comprises ³He, ⁴He, or a combination of ³He and ⁴He.

18. The apparatus of claim 10, wherein the liquid He bath comprises ³He.

19. A heat exchanging apparatus for superconducting integrated circuits operating at milliKelvin temperatures, the apparatus comprising:
a substrate having a first surface and a second surface opposite from each other, the first surface being coupled to a dissipative element having at least two electrical terminals;
a thermal micro-via positioned in physical contact with a portion of the dissipative element and extending toward the second surface in a perpendicular direction; and
a heat spreader being coupled to the thermal micro-via and extending from the second surface.

20. The apparatus of claim 19, wherein the heater spreader comprises a non-superconducting metal that is maintained at a temperature of less than 100 milliKelvin.
